(19) United States
(12) Patent Application Publication
(10) Pub. No.: US 2019/0319190 A1
(43) Pub. Date: Oct. 17, 2019

(54) MASK SHEET FRAME BODY BONDING APPARATUS AND MANUFACTURING METHOD OF VAPOR DEPOSITION MASK

(71) Applicant: Sharp Kabushiki Kaisha, Sakai City, Osaka (JP)

(72) Inventor: Kenta NAKAMURA, Sakai City (JP)

(21) Appl. No.: 16/467,163

(22) PCT Filed: Jul. 10, 2017
(86) PCT No.: PCT/JP2017/025153

§ 371 Date: Jun. 6, 2019

(51) Int. Cl. H01L 51/00; B23K 26/22; B21D 35/00; H01L 27/32; H01L 51/52; H01L 51/56

(52) U.S. Cl. CPC H01L 51/0011; B23K 26/22; B21D 35/00; C23C 14/042; H01L 51/001; H01L 51/524; H01L 51/56; H01L 27/3244

(57) ABSTRACT

Provided are a mask sheet frame body bonding apparatus that allows a mask sheet to be bonded to a frame body without producing a crease in a mask pattern by a simple method, and a manufacturing method of a vapor deposition mask. The mask sheet frame body bonding apparatus bonds the mask sheet provided with the mask pattern to the frame. The mask sheet frame body bonding apparatus includes grippers configured to hold gripper end portions of the mask sheet and apply a tensile force to the mask sheet, and a roller serving as a pressing members other than the frame and configured to press at least a side of the mask sheet subjected to tensile force that is opposite to the frame and is a front face of the mask sheet, between the mask pattern and holding positions of the grippers.

### TECHNICAL FIELD

The disclosure relates to a mask sheet frame body bonding apparatus configured to bond a mask sheet provided with a mask pattern to a frame body, and a manufacturing method of a vapor deposition mask.

### BACKGROUND ART

An organic electroluminescence (hereinafter referred to as “organic EL”) display is a display formed by arranging a plurality of organic light-emitting diodes serving as luminescent bodies into a matrix shape on a substrate.

An organic light-emitting diode is made from three types of elements, respectively emitting the three primary colors of red, green, and blue (RGB). Each element is formed by vapor-depositing organic luminescent materials for each RGB color onto the substrate. The luminescent materials need to be formed into a film in a pattern shape for each RGB color. To do this, a metal mask that is open at desired pattern positions and covers all other areas is required.

This metal mask is obtained by, for example, subjecting a thin plate made of a metal having a thickness of 30 μm or less to demetallization in areas where a pattern is to be formed in an etching process. The etched thin metal plate is cut into a sheet shape to form a metal mask sheet. The metal mask sheet is, for example, attached to a fixed frame in accordance with a process, and supplied to the process. When the metal mask sheet is attached and fixed to the fixed frame, tension needs to be constantly applied to the metal mask sheet in order to prevent the occurrence of scratches, creases, and recesses, and to prevent a reduction in a dimensional accuracy of machining.

Nevertheless, the task of attaching the metal mask sheet to the fixed frame is often performed by a person, often resulting in the tension being applied slightly unevenly and, as a result, the occurrence of creases and, in turn, defective products.

Here, a transport device of a metal mask sheet disclosed in PTL 1 includes a stretching means for applying tension to the metal mask sheet while securing a front face of the metal mask sheet through suction by a suction means, and an image taking means for reading an alignment mark provided on the metal mask sheet. As a result, an amount of shift in the position of the alignment mark read by the image taking means immediately before and immediately after suction of the metal mask sheet is found, and the tension in a width direction is then adjusted by the stretching means to compensate for this shift.

### CITATION LIST

### Patent Literature

PTL 1: JP 2015-199607A (published on Nov. 12, 2015)

### SUMMARY

### Technical Problem

Nevertheless, in the transport device of the metal mask sheet disclosed in PTL 1 in the related art described above, the tension needs to be slightly adjusted by the stretching means in order to compensate for the shift so that creases are eliminated. As a result, in addition to the stretching means, a stretching means that equally and accurately adjusts and applies tension to the metal mask sheet is required, resulting in the problems of high cost and the need for time for adjustment.

In view of the problems in the related art described above, an object of the disclosure is to provide a mask sheet frame body bonding apparatus that allows a mask sheet to be bonded to a frame body without producing a crease in a mask pattern by a simple method, and a manufacturing method of a vapor deposition mask.

### SOLUTION TO PROBLEM

To solve the above-described problems, a mask sheet frame body bonding apparatus according to an aspect of the disclosure is a mask sheet frame body bonding apparatus configured to bond a mask sheet provided with a mask pattern to a frame body, including a tension jig configured to hold both end portions of the mask sheet and apply a tensile force to the mask sheet, and a pressing member other than the frame body configured to press at least a side of the mask sheet subjected to the tensile force that is opposite to the frame body and is a front face of the mask sheet, between the mask pattern and a holding position of the tension jig.

To solve the above-described problems, a manufacturing method of a vapor deposition mask according to an aspect of the disclosure is a manufacturing method of a vapor deposition mask obtained by bonding a mask sheet to a frame body using the mask sheet frame body bonding apparatus described above, including a tension step for holding the mask sheet at both ends and applying a tensile force to the mask sheet, a contacting step for fitting the mask pattern inside an opening of the frame body and bringing the frame body into contact with the mask sheet, a pressing step for pressing a front face of the mask sheet by a pressing member, a bonding step for bonding the mask sheet to the frame body, a pressing releasing step for releasing the pressing applied to the mask sheet by the pressing member after bonding completion, a tensile force releasing step for releasing the tensile force applied to the mask sheet, and a cutting step for cutting end portions of the mask sheet to manufacture the vapor deposition mask, in that order.

### Advantageous Effects of Disclosure

According to an aspect of the disclosure, an effect of providing a mask sheet frame body bonding apparatus that allows a mask sheet to be bonded to a frame body without producing a crease in a mask pattern by a simple method, and a manufacturing method of a vapor deposition mask can be attained.

### BRIEF DESCRIPTION OF DRAWINGS

FIG. 1A is a plan view illustrating a mask sheet frame body bonding apparatus of a first embodiment of the disclosure, illustrating a state where a mask sheet is fixed to a frame, FIG. 1B is a plan view illustrating a method of applying tension to the mask sheet, and FIG. 1C is a cross-sectional view taken along line A-A in the direction of arrows in FIG. 1A.

FIG. 2A is a cross-sectional view illustrating a configuration of an OLED panel, and FIG. 2B is a flowchart illustrating a manufacturing method of the OLED panel.

FIG. 3 is a schematic cross-sectional view illustrating a vapor deposition step of the OLED panel.

FIG. 4 is a flowchart illustrating a method for bonding the mask sheet to the frame.

FIG. 5 is a plan view illustrating a configuration of a vapor deposition mask obtained by welding all mask sheets to the frame.

FIG. 6A is a plan view illustrating a mask sheet frame body bonding apparatus of a modified example of the first embodiment of the disclosure, illustrating a state where a mask sheet is fixed to a frame, FIG. 6B is a cross-sectional view taken along line A-A in the direction of arrows in FIG. 6A, and FIG. 6C is a cross-sectional view of another modified example.

FIG. 7A is a plan view illustrating a mask sheet frame body bonding apparatus of another modified example of the first embodiment of the disclosure, illustrating a state where the mask sheet is fixed to the frame, and FIG. 7B is a cross-sectional view taken along line A-A in the direction of arrows in FIG. 7A.

FIG. 8A is a plan view illustrating a mask sheet frame body bonding apparatus of a second embodiment of the disclosure, illustrating a configuration of a divided roller, FIG. 8B is a plan view illustrating a state where two divided rollers are used in accordance with a width of a mask sheet, and FIG. 8C is a plan view illustrating a state where three divided rollers are used in accordance with the width of the mask sheet.

FIG. 9 is a plan view illustrating a mask sheet frame body bonding apparatus of a third embodiment of the disclosure, illustrating a configuration of a divided roller arranged on one shaft when a mask sheet is bonded to a frame.

FIG. 10 is a plan view illustrating a modified example of the mask sheet frame body bonding apparatus of the third embodiment of the disclosure, illustrating a configuration of divided rollers arranged in a zig-zag shape on two shafts when the mask sheet is bonded to the frame.

### DESCRIPTION OF EMBODIMENTS

### First Embodiment

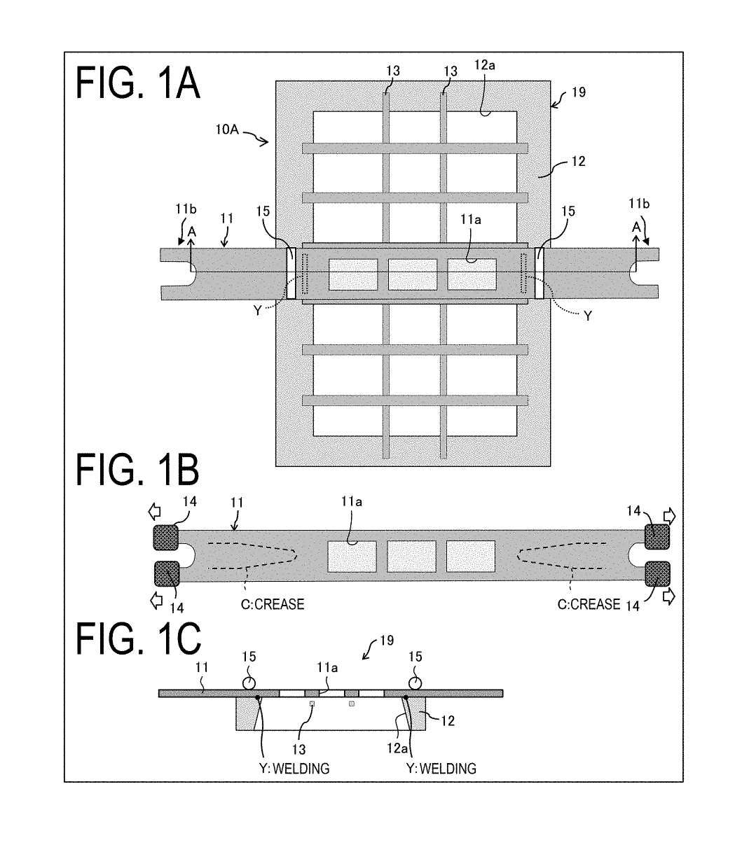

A description follows regarding one embodiment of the disclosure, on the basis of FIGS. 1A to 7B.

### Overview of Manufacturing Method of OLED Panel

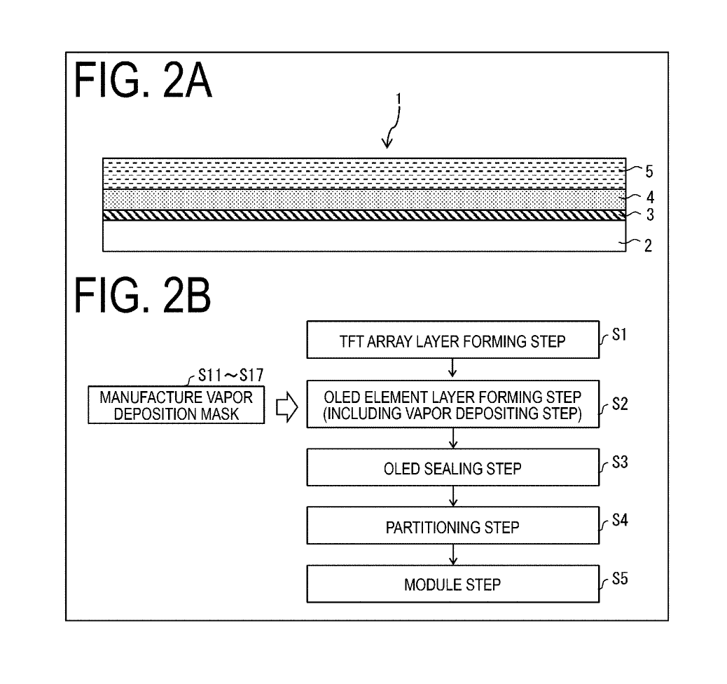

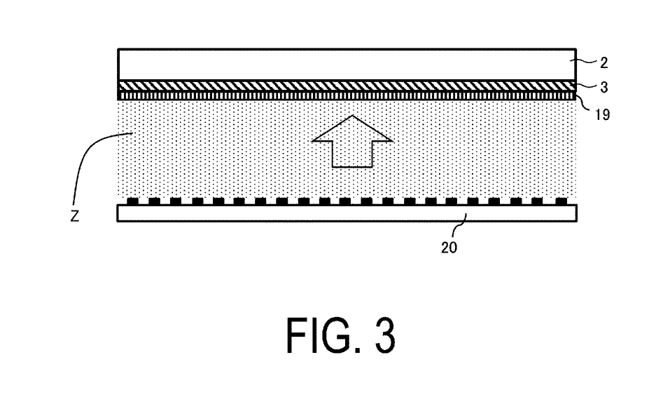

A manufacturing method of an organic light-emitting diode (OLED) panel 1 serving as a display panel and including a mask sheet frame body bonding apparatus of the present embodiment is described below on the basis of FIGS. 2A, 2B, and 3. FIG. 2A is a cross-sectional view illustrating a configuration of the OLED panel 1. FIG. 2B is a flowchart illustrating the manufacturing method of the OLED panel 1. FIG. 3 is a schematic cross-sectional view illustrating a vapor deposition step of the OLED panel 1.

The OLED panel 1 is a panel provided with a luminescent body made of organic electroluminescence (hereinafter referred to as “organic EL”), and includes a substrate 2, a thin-film transistor (TFT) array layer 3, an OLED element layer 4, and a protection glass 5, layered in that order, as illustrated in FIG. 2A. The TFT array layer 3 includes a thin film transistor, a signal line, and the like. The OLED element layer 4 is a layer in which three types of elements that respectively emit the three prime colors RGB are arranged into a matrix shape in a planar manner. Each element is formed by vapor depositing organic luminescent materials for each RGB color onto the substrate. The OLED element layer 4 further includes an electrical function layer and a cathode electrode. The protection glass 5 seals the RGB elements of the OLED element layer 4.

When the OLED panel 1 is manufactured, first the TFT array layer 3 is formed on the substrate 2, as illustrated in FIG. 2B (S1). Next, the OLED element layer 4 is formed on the TFT array layer 3 using a vapor deposition mask (S2). This step is called an OLED element layer forming step, and this OLED element layer forming step includes a vapor depositing step.

In the vapor depositing step, as illustrated in FIG. 3, a mask sheet 11 including a plurality of through-holes is vapor-deposited on a front face of the TFT array layer 3 formed on a front face of the substrate 2, and vapor deposition particles Z serving as an organic luminescent material vaporized or sublimated by a vapor deposition source 20 are vapor deposited on the TFT array layer 3 over a vapor deposition mask 19 under a vacuum. As a result, a vapor deposition pattern is formed in a pattern corresponding to the through-holes of the vapor deposition mask 19.

Subsequently, as illustrated in FIG. 2B, the OLED element layer 4 is sealed by the protection glass 5 (S3), partitioned, that is, singulated (S4), and formed into the OLED panel 1 (S5). In this S5, a movement driver, a polarizing plate, a touch panel, and the like are mounted on the OLED panel 1.

### Mask Sheet Frame Body Bonding Apparatus

In the vapor deposition step in the manufacture of the OLED panel 1, a mask sheet frame body bonding apparatus 10A is used in the present embodiment to prepare the vapor deposition mask 19.

A configuration of the mask sheet frame body bonding apparatus 10A of the present embodiment will now be described on the basis of FIGS. 1A, 1B, and 1C. FIG. 1A is a plan view illustrating the mask sheet frame body bonding apparatus 10A of the present embodiment, illustrating a state where the mask sheet 11 is fixed to a frame 12. FIG. 1B is a plan view illustrating a method for applying tension to the mask sheet 11. FIG. 1C is a cross-sectional view taken along line A-A in the direction of the arrows in FIG. 1A.

As described above, in the vapor deposition step, the vapor deposition particles Z are vapor deposited on the TFT array layer 3 via the vapor deposition mask 19. The vapor deposition mask 19, as illustrated in FIGS. 1A and 1C, is obtained by welding the mask sheet 11 onto the frame 12 serving as a frame body. Moreover, while only one mask sheet 11 is described relative to the frame 12 in FIG. 1A, a plurality of the mask sheets 11 are arranged side by side in the actual vapor deposition mask 19 so as to completely block an opening 12a of the frame 12. Further, while both end portions of the mask sheet 11 are extended to an outer side of the frame 12 in FIGS. 1A and 1C, with the vapor deposition mask 19, a portion extending to the outer side of the frame 12 is cut and removed.

The mask sheet 11, as illustrated in FIG. 1B, is obtained by forming a plurality of mask patterns 11a corresponding to the RGB elements on a metal sheet formed into a strip shape. As a base material of the mask sheet 11, an invar material or the like having a thickness of from 10 to 50 μm is used, for example.

The plurality of mask patterns 11a formed are arranged in a center portion of the mask sheet 11, and both end portions of the mask sheet 11 constitute two gripper end portions 11b, 11b capable of gripping. Note that, while the mask pattern 11a is described in the form of a blank area in FIG. 1B, a plurality of openings of 1 mm or less are actually formed to accommodate each RGB pixel. A single mask pattern 11a is, for example, formed correspondingly to a size of a 5-inch panel or the like.

The mask sheet 11 is formed in a sheet shape and thus, when the mask sheet 11 is used as the vapor deposition mask 19 in the vapor deposition step, a support body that supports the mask sheet 11 is required. Here, the mask sheet 11 is generally used in the form of the vapor deposition mask 19 obtained by bonding the mask sheet 11 to the frame 12 serving as the frame body by welding, as illustrated in FIG. 1A. In the present embodiment, an auxiliary frame 13 is formed on the frame 12. When the frame 12 is large, it is preferable to provide the auxiliary frame 13 in this way.

In the present embodiment, when the mask sheet 11 is bonded to the frame 12 and the vapor deposition mask 19 is manufactured, the mask sheet frame body bonding apparatus 10A is used.

The mask sheet frame body bonding apparatus 10A of the present embodiment, as illustrated in FIG. 1B, includes grippers 14, 14 as tension jigs configured to hold gripper end portions 11b, 11b of both end portions of the mask sheet 11 and apply a tensile force to the mask sheet 11. The grippers 14, 14 sandwich the gripper end portions 11b, 11b by a mechanism such as a clothes pin, for example.

Further, the mask sheet frame body bonding apparatus 10A of the present embodiment includes a roller 15 as a pressing member and a cylindrical member that presses at least one of a front face and a rear face of the mask sheet 11 subjected to the tensile force, between the mask pattern 11a and the holding positions of the grippers 14. According to an aspect of the disclosure, the cylindrical member does not necessarily have to be a rotating body such as the roller 15, and only needs to have a curved face.

Further, in the present embodiment, a length of the roller 15 in an axial direction is the same as a width of the mask sheet 11. However, the length of the roller 15 in the axial direction is not limited thereto, and may be greater than the width of the mask sheet 11, and is at least greater than a width welded.

A pressing target of the roller 15 is preferably at least a side of the mask sheet 11 that is opposite to the frame body and is the front face of the mask sheet 11. One of the front face and the rear face can be set as the pressing target. In this case, a method can be adopted in which the mask sheet 11 is sandwiched and pressed by the frame 12 and the roller 15 by bringing the frame 12 into abutment with the mask sheet 11 from a lower side of the mask sheet 11 and pressing the roller 15 from an upper side of the mask sheet 11, for example. Note that the frame 12 may be arranged on the upper side of the mask sheet 11. When this is taken into account, the pressing applied by the roller 15 to the mask sheet 11 can be to one of the front face and the rear face of the mask sheet 11.

Such a method, as described in detail later, has the effect of blocking a crease C, which occurs when the gripper end portions 11b, 11b are held by the grippers 14, 14, at the pressing position, preventing the crease C from extending to the mask pattern 11a, and facilitating a welding Y upon adherence of the mask sheet 11 to the frame 12.

Alternatively, in a position other than that of the frame 12, one of the front face and the rear face of the mask sheet 11 can be pressed using a single roller 15. In this case, when only the rear face of the mask sheet 11 is pressed, for example, preferably a tensile force is applied by the grippers 14, 14 with the gripper end portions 11b, 11b of both end portions of the mask sheet 11 positioned lower than the roller 15. As a result, the pressing force of the roller 15 can be increased.

Further, both the front face and the rear face of the mask sheet 11 can be established as pressing targets of the roller 15. As a result, the mask sheet 11 can be held by two of the rollers 15, 15, enhancing the effect of blocking the crease C.

Here, as a support method of the roller 15, when the roller 15 is pressed from the lower side of the mask sheet 11, for example, the roller 15 can be supported by being suspended by a wire or the like. On the other hand, when the mask sheet 11 is pressed from both the rear face and the front face sides by the two rollers 15, 15, preferably each of the rollers 15, 15 is provided with an independent support mechanism. As a result, the two rollers 15, 15 can be independently driven and pressed.

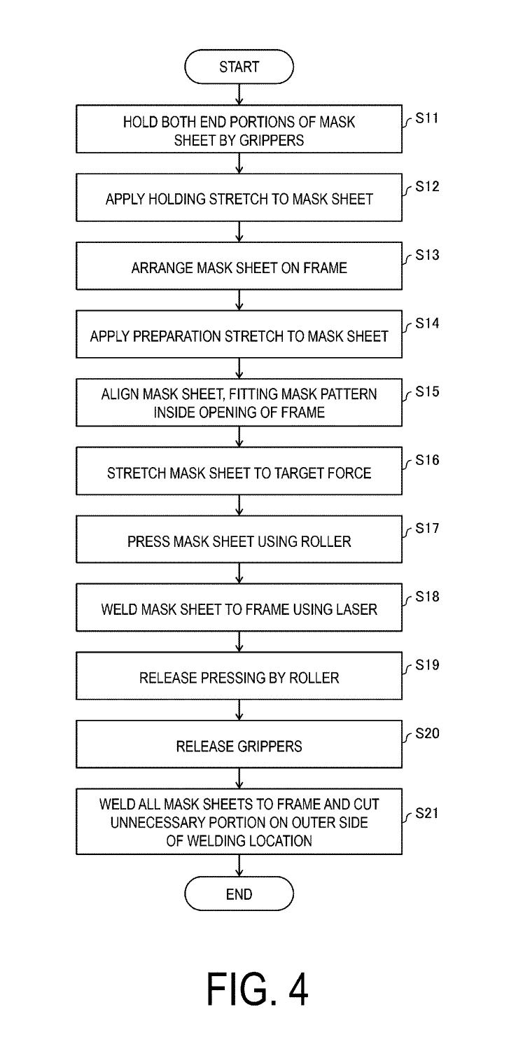

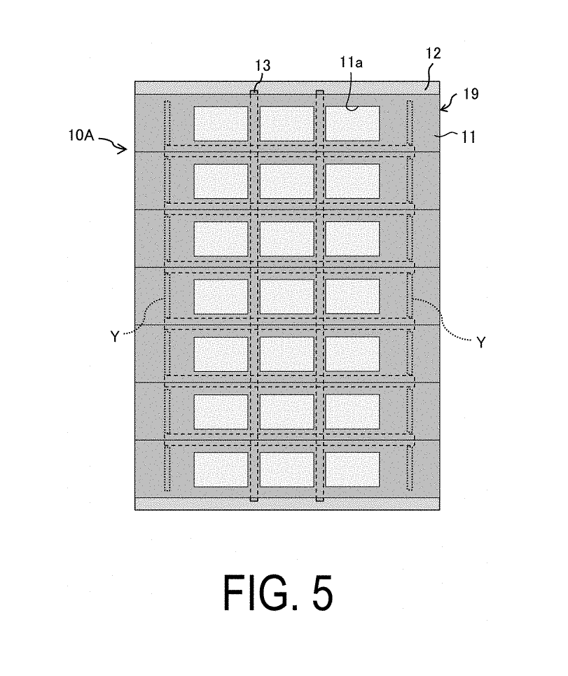

The following describes a method for bonding the mask sheet 11 to the frame 12 of the mask sheet frame body bonding apparatus 10A of the configuration described above on the basis of FIG. 4. FIG. 4 is a flowchart illustrating the method for bonding the mask sheet 11 to the frame 12. FIG. 5 is a plan view illustrating a configuration of a vapor deposition mask obtained by welding all mask sheets to the frame. Moreover, a control target of the flowchart illustrated in FIG. 4 is a controller (not illustrated) of the mask sheet frame body bonding apparatus 10A.

As illustrated in FIG. 4, first the gripper end portions 11b, 11b at both ends of the mask sheet 11 are held by the grippers 14, 14 (S11), and the mask sheet 11 is pulled by a weak force to such an extent that the holds are preserved (S12). Here, this is called a holding stretch. Next, the mask sheet 11 is arranged on an upper side of the frame 12 (S13). At this time, the mask sheet 11 is pulled by a force to such an extent that the mask sheet 11 does not droop (S14). Here, this is called a preparation stretch. In the preparation stretch, a constant tensile force is applied. In this state, the mask pattern 11a of the mask sheet 11 is aligned so as to fit inside the opening 12a of the frame 12 (S15). At this time, the mask sheet 11 is stretched to a target force (S16). Note that the stretching at this time is performed while adjusting the position of the mask sheet 11 so that the mask pattern 11a fits inside the opening 12a of the frame 12, and thus the tensile force is gradually increased to the target force, and is not a constant tensile force.

When this task is performed, normally, as illustrated in FIG. 1B, the crease C occurs on the mask sheet 11, between the holding portions of the grippers 14, 14 and the mask pattern 11a. Here, to ensure that this crease C does not extend to the mask pattern 11a, the front face of the mask sheet 11 is pressed by the roller 15 in the present embodiment (S17). Specifically, as illustrated in FIG. 1C, the mask sheet 11 mounted on the frame 12 is pressed by the roller 15 from the upper face of the mask sheet 11. As a result, the crease C no longer extends inward of the pressing part portion of the roller 15.

Next, in this state, the mask sheet 11 is welded to the frame 12 using a laser (S18). At this time, for example, the mask sheet 11 is welded while pressed by the roller 15. However, the disclosure is not limited thereto, and welding may be performed after releasing the pressing of the roller 15.

During welding, as illustrated in FIGS. 1 A and 1C, the mask sheet 11 is welded by spot-irradiating a laser on a contact portion of the mask sheet 11 with the frame 12, and thus the mask sheet 11 is fused, making it possible to spot-weld the mask sheet 11 to the frame 12 by the welding portion Y.

Once welding is completed, the pressing of the roller 15 is released (S19), and the grippers 14, 14 of the gripper end portions 11b, 11b are released (S20). At this time, a quality inspection is conducted to see if the mask sheet 11 has been favorably welded to the frame 12 without the crease C in the mask pattern 11a.

Next, a plurality of the mask sheets 11 are similarly welded to the frame 12. When all welding is completed, outside portions, that is, end portions of the welding Y of the mask sheet 11 are cut (S21).

As a result, as illustrated in FIG. 5, the mask sheet 11, that is, the vapor deposition mask 19 fixed to the frame 12 is completed.

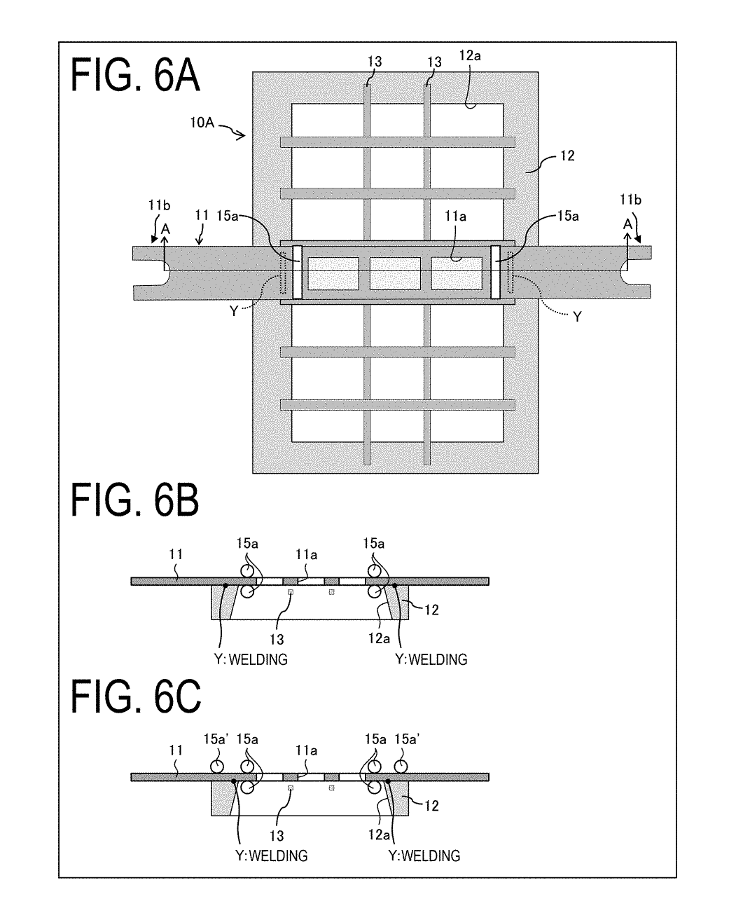

Note that, in the description above, the pressing position of the roller 15 on the mask sheet 11 is described as the upper side portion of the frame 12 of the mask sheet 11. However, the pressing position of the roller 15 on the mask sheet 11 is not limited thereto. For example, as illustrated in FIGS. 6A and 6B, the pressing position of a roller 15a can be established as an inner side of the frame 12, on an outer side of the mask pattern 11a. In this case, the rollers 15a, 15a serving as pressing members are preferably provided to both the front face and the rear face of the mask sheet 11, and press the mask sheet 11 by sandwiching the mask sheet 11. Further, in this case, as illustrated in FIG. 6C, for example, the front face of the mask sheet 11 on the frame 12 is preferably pressed by a roller 15a′. As a result, the mask sheet 11 on the frame 12 can be adhered to the frame 12, making it easy to perform the welding Y.

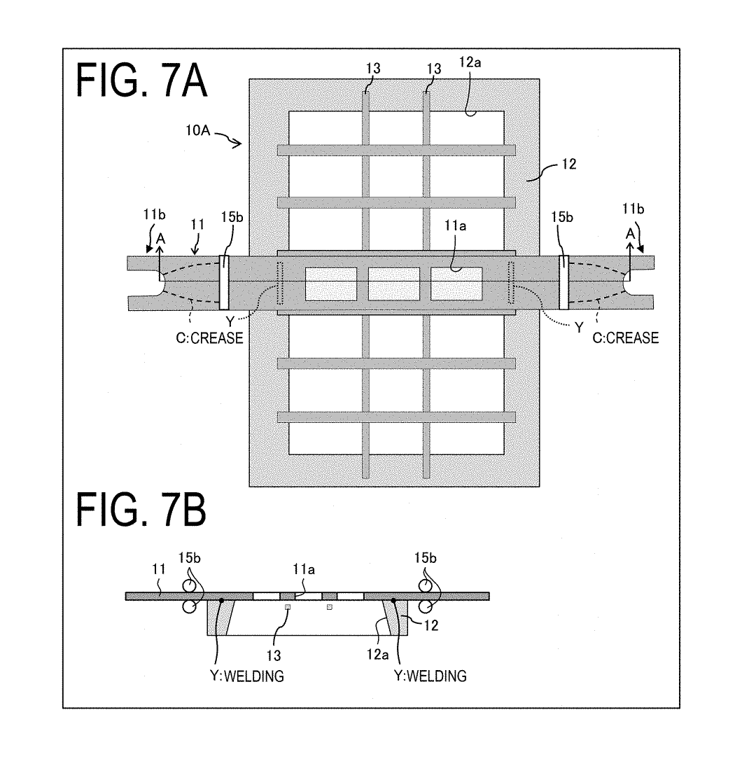

Further, as the pressing position of the rollers 15b on the mask sheet 11, the rollers 15b, 15b can be arranged on the outer sides of the frame 12, as illustrated in FIGS. 7A and 7B. In this case as well, the rollers 15b, 15b may be provided to only the front face of the mask sheet 11, but are preferably provided to both the front face and the rear face and press the mask sheet 11 by sandwiching the mask sheet 11.

Thus, the mask sheet frame body bonding apparatus 10A of the present embodiment bonds the mask sheet 11 provided with the mask pattern 11a to the frame 12 serving as the frame body. Further, the mask sheet frame body bonding apparatus 10A includes the grippers 14, 14 as tension jigs configured to hold the gripper end portions 11b, 11b of the mask sheet 11 and apply a tensile force to the mask sheet 11, and the roller 15 other than the frame 12 configured to press at least the side of the mask sheet 11 subjected to tensile force that is opposite to the frame body and is the front face of the mask sheet 11, between the mask pattern 11a and the holding positions of the grippers 14, 14.

Accordingly, the crease C is stopped at the pressing position of the roller 15 to the mask sheet 11. As a result, the portion of the mask sheet 11 provided with the mask pattern 11a is without the crease C. Thus, the mask sheet 11 is bonded to the frame 12 without the crease C and with the tensile force uniformly applied, making it possible to perform the vapor deposition task using the vapor deposition mask 19 of high quality. As a result, it is possible to reduce the occurrence of defective products.

Further, in the present embodiment, a method for avoiding the occurrence of the crease C in the portion of the mask pattern 11a, which is the portion that requires such avoidance, rather than eliminating all occurrences of the crease C in the mask sheet 11, is adopted. Specifically, according to the method, it is possible to achieve a reduction in the occurrence of the crease C by the roller 15, which is a simple member configured to press the area in front of the mask pattern 11a of the mask sheet 11. Accordingly, additional adjustment of the tensile force of the grippers 14, 14 is also not required, saving time as well.

Thus, it is possible to provide the mask sheet frame body bonding apparatus 10A that allows the mask sheet 11 to be bonded to the frame 12 without producing the crease C in the mask pattern 11a by a simple method.

Further, in the mask sheet frame body bonding apparatus 10A of the present embodiment, the roller 15 is preferably made from a cylindrical member. Accordingly, the mask sheet 11 is pressed by the roller 15 made from a cylindrical member, and thus the pressed face is curved. As a result, the mask sheet 11 is uniformly pressed without being scratched, making it possible to apply uniform tension to the mask pattern 11a.

Further, in the mask sheet frame body bonding apparatus 10A of the present embodiment, the roller 15 can press the frame 12, sandwiching the mask sheet 11, more toward both end portion sides of the mask sheet 11 than the bonding portion of the mask sheet 11 and the frame 12.

Accordingly, the mask sheet 11 can be pressed while sandwiched between the frame 12 and the roller 15. As a result, the frame 12 can be utilized as a pressing member. Further, the mask sheet 11 is welded to the frame 12 in a state where an adhesive strength of the frame 12 to the mask sheet 11 is increased, making it possible to perform welding efficiently.

Further, in the mask sheet frame body bonding apparatus 10A of the present embodiment, the roller 15 can be provided to both the front face and the rear face of the mask sheet 11, and press the mask sheet 11 by sandwiching the mask sheet 11. As a result, the crease C extended from the holding positions of the grippers 14, 14 toward the interior can be reliably blocked at the pressed face.

Further, in the mask sheet frame body bonding apparatus 10A of the present embodiment, the roller 15a can be positioned on the inner side of the frame 12. As a result, the crease C can be suppressed immediately in front of the mask pattern 11a. Further, when a laser is irradiated from the upper side of the mask sheet 11 and the mask sheet 11 is bonded to the frame 12 by welding, the roller 15a does not interfere.

Further, in the mask sheet frame body bonding apparatus 10A of the present embodiment, the roller 15b can be positioned on the outer side of the frame 12. As a result, the outer side of the frame 12 is pressed, simplifying the pressing task. Further, when a laser is irradiated from the upper side of the mask sheet 11 and the mask sheet 11 is bonded to the frame 12 by welding, the roller 15b does not interfere.

Further, in the mask sheet frame body bonding apparatus 10A of the present embodiment, the length of the rollers 15, 15a, 15a′, 15b in a direction orthogonal to a direction in which the tensile force is applied to the mask sheet 11 is preferably longer than a welding length when the mask sheet 11 is welded to the frame 12. As a result, it is possible to prevent the crease C from extending outward beyond the welding length and adversely impacting the mask pattern 11a.

Further, a manufacturing method of the vapor deposition mask 19 of the present embodiment manufactures the vapor deposition mask 19 obtained by bonding the mask sheet 11 to the frame 12 using the mask sheet frame body bonding apparatus 10A of the present embodiment. Then, the manufacturing method of the vapor deposition mask 19 includes a tension step for holding the mask sheet 11 at both ends and applying a tensile force to the mask sheet 11, a contacting step for fitting the mask sheet 11 inside the opening 12a of the frame 12 and bringing the frame 12 into contact with the mask sheet 11, a pressing step for pressing the front face of the mask sheet 11 by the rollers 15, 15a, 15a′, 15b, a bonding step for bonding the mask sheet 11 to the frame 12, a pressing releasing step for releasing the pressing applied to the mask sheet 11 by the rollers 15, 15a, 15a′, 15b after bonding completion, a tensile force releasing step for releasing the tensile force applied to the mask sheet 11, and a cutting step for cutting the end portions of the mask sheet 11 to manufacture the vapor deposition mask 19, in that order.

Thus, when the vapor deposition mask 19 is manufactured, it is possible to provide a manufacturing method of the vapor deposition mask 19 that allows the mask sheet 11 to be bonded to the frame 12 without producing the crease C in the mask pattern 11a by a simple method.

### Second Embodiment

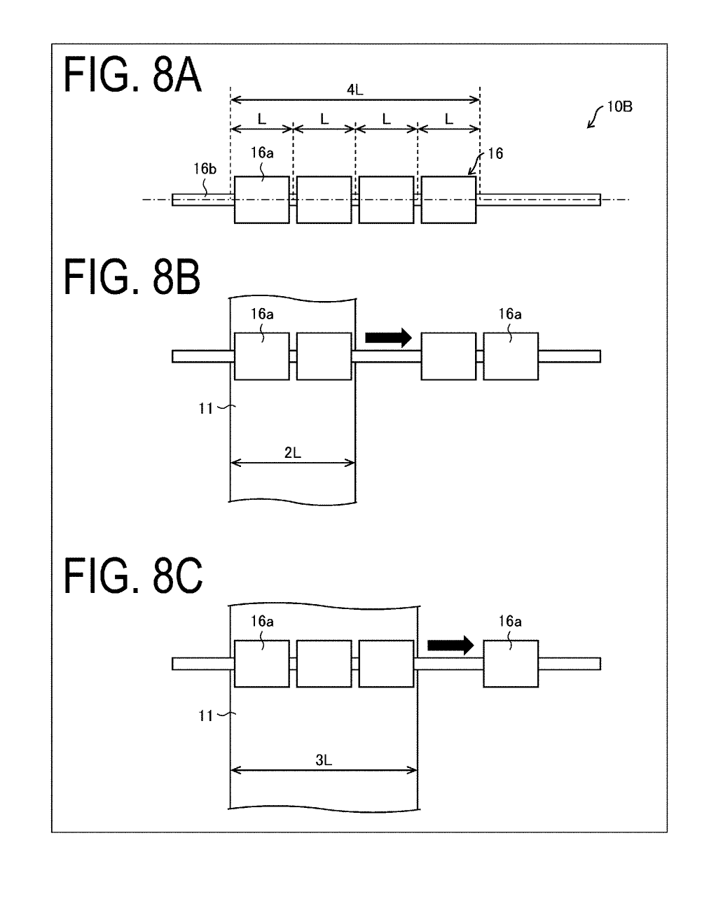

A description follows regarding another embodiment of the disclosure, on the basis of FIGS. 8A, 8B, and 8C. Note that components other than those described in the present embodiment are the same as those in the first embodiment in configuration. For convenience of descriptions, members having the same functions as those of the members illustrated in the diagrams in the first embodiment are denoted by the same reference numerals, and descriptions thereof will be omitted.

In the mask sheet frame body bonding apparatus 10A of the first embodiment, the length of the rollers 15, 15a, 15b in the axial direction matches the width of the mask sheet 11. In comparison, a mask sheet frame body bonding apparatus 10B of the present embodiment differs in that a roller 16 serving as a pressing member includes a plurality of divided rollers 16a.

The configuration of the roller 16 of the mask sheet frame body bonding apparatus 10B of the present embodiment will now be described on the basis of FIGS. 8A, 8B, and 8C. FIG. 8A is a plan view illustrating the mask sheet frame body bonding apparatus 10B of the present embodiment, illustrating the configuration of the roller 16 including the plurality of divided rollers 16a. FIG. 8B is a plan view illustrating a state where two divided rollers 16a are used in accordance with the width of a mask sheet 11. FIG. 8C is a plan view illustrating a state where three divided rollers 16a are used in accordance with the width of the mask sheet 11.

In the roller 16 of the present embodiment, four of the divided rollers 16a are provided to a shaft 16b, for example. The shaft 16b is longer than a length of the four divided rollers 16a, and each of the divided rollers 16a is movable on the shaft 16b. The lengths of each of the divided rollers 16a are a length L, for example, and are equal to each other in the present embodiment. However, according to an aspect of the disclosure, the lengths of the plurality of divided rollers 16a may be different from each other. Then, in the present embodiment, the number of divided rollers 16a used is determined in accordance with the width of the mask sheet 11.

For example, as illustrated in FIG. 8B, two of the divided rollers 16a are used for pressing when the width of the mask sheet 11 is 2 L. Further, for example, as illustrated in FIG. 8C, three of the divided rollers 16a are used for pressing when the width of the mask sheet 11 is 3 L. Note that, in FIGS. 8A and 8B, the divided rollers 16a not used are moved laterally along the shaft 16b.

Thus, in the mask sheet frame body bonding apparatus 10B of the present embodiment, a plurality of the rollers 16 serving as the pressing members are arranged in the direction orthogonal to the direction in which the tensile force is applied to the mask sheet 11. Then, the number of divided rollers 16a having a total length corresponding to the width of the mask sheet 11 press the mask sheet 11.

For example, according to the type of the OLED panel 1 serving as the display panel, the width of the mask sheets 11 may differ. In this case, as in the first embodiment, the roller 15 having a single length may be shorter than the width of the mask sheet 11. In the present embodiment, in preparation for such a case, the roller 16 includes, from the start, a plurality of the divided rollers 16a arranged in the direction orthogonal to the direction in which the tensile force is applied to the mask sheet 11. Then, at the time of use, the mask sheet 11 is pressed using the number of divided rollers 16a matching the width of the mask sheet 11. For example, the mask sheet 11 having a short width is pressed using two divided rollers 16a, and the mask sheet 11 having a long width is pressed using three divided rollers 16a.

As a result, it is possible to provide the mask sheet frame body bonding apparatus 10B capable of versatility.

### Third Embodiment

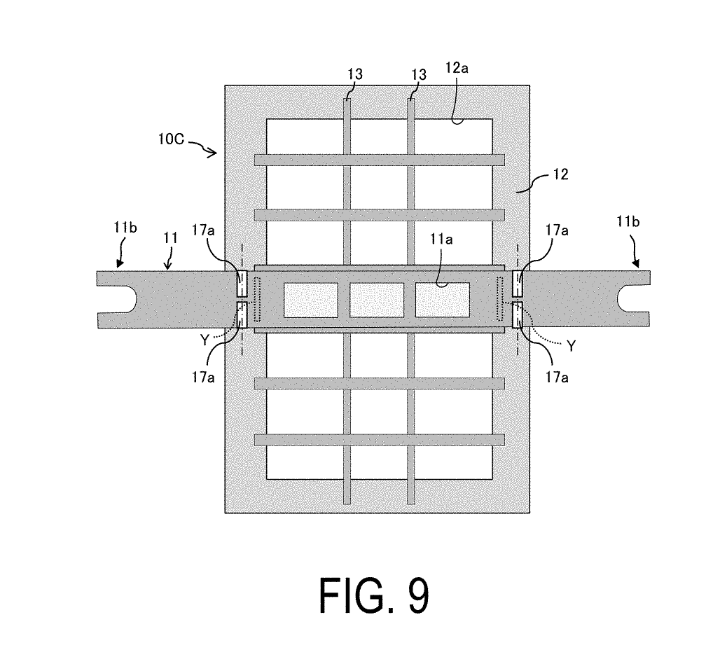

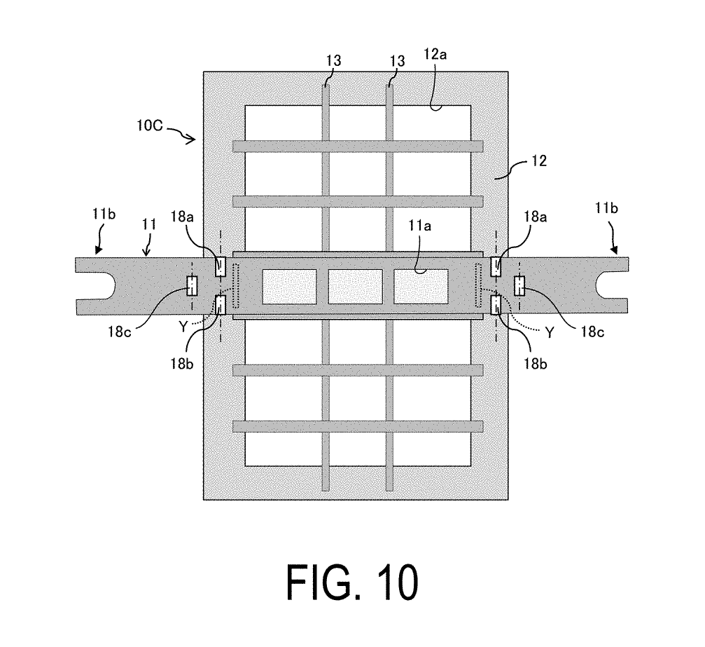

A description follows regarding yet another embodiment of the disclosure, on the basis of FIGS. 9 and 10. Note that components other than those described in the present embodiment are the same as those in the first and second embodiments in configuration. For convenience of descriptions, members having the same functions as those of the members illustrated in the diagrams in the first and second embodiments are denoted by the same reference numerals, and descriptions thereof will be omitted.

In the mask sheet frame body bonding apparatus 10A of the first embodiment, the length of the rollers 15, 15a, 15b in the axial direction matches the width of the mask sheet 11. In comparison, a mask sheet frame body bonding apparatus 10C of the present embodiment differs in that a pressing member includes a plurality of divided rollers 17a and divided rollers 18a, and each of the divided rollers 17a and the divided rollers 18a are provided on the same shaft or on two shafts.

A configuration of the plurality of divided rollers 17a serving as pressing members of the mask sheet frame body bonding apparatus 10C of the present embodiment will now be described on the basis of FIG. 9, and FIG. 10. FIG. 9 is a plan view illustrating the mask sheet frame body bonding apparatus C of the present embodiment, illustrating a configuration of the divided roller 17a arranged on one shaft when the mask sheet 11 is bonded to a frame 12. FIG. 10 is a plan view illustrating a modified example of the mask sheet frame body bonding apparatus 10C of the present embodiment, illustrating a configuration of the divided rollers 18a, 18b and the divided roller 18c arranged in a zig-zag shape on two shafts when the mask sheet 11 is bonded to the frame 12.

As illustrated in FIG. 9, for example, two of the divided rollers 17a of the present embodiment are provided on one shaft, and the total width of the two divided rollers 17a substantially matches the width of the mask sheet 11.

Accordingly, even when the width of a single divided roller 17a is less than the width of the mask sheet 11, it is possible to satisfy the width of the mask sheet 11 by arranging, for example, two of the divided rollers 17a on the same shaft. As a result, in terms of the width of the mask sheet 11, the mask sheet 11 can be pressed based on the same effects as when pressed using, for example, the roller 15, which is a single pressing member matching the width of the mask sheet 11.

Further, in the mask sheet frame body bonding apparatus 10C of the present embodiment, the method for arranging the divided rollers is not necessarily limited to one shaft on one side of the mask sheet 11.

For example, as illustrated in FIG. 10, the divided rollers 18a, 18b and the divided roller 18c serving as a plurality of pressing members can be provided in a zig-zag shape on at least two shafts.

That is, for example, the divided rollers 18a, 18b are provided spaced apart on one shaft as illustrated in FIG. 9, and one divided roller 18c is provided across a center line in the longitudinal direction of the mask sheet 11, on the outer side of the divided rollers 18a, 18b. As a result, the divided rollers 18a, 18b, 18c are arranged in a zig-zag shape on two shafts. Note that the length of the divided roller 18c is longer than a gap between the divided rollers 18a, 18b.

Thus, the divided rollers 18a, 18b, 18c are arranged on the two shafts, thereby blocking the crease C at at least two stages, and thus increasing the effect of blocking the crease C. On the other hand, the divided rollers 18a, 18b, 18c are arranged in a zig-zag shape on the two shafts, thereby allowing a decrease in the number of pressing members, and thus making it possible to block the crease C efficiently using a small number of pressing members.

Further, in the mask sheet frame body bonding apparatus 10C of the present embodiment, when the plurality of rollers 18a, 18b, 18c provided in a zig-zag shape on at least two shafts are viewed from both end sides of the mask sheet 11, the plurality of rollers 18a, 18b, 18c are arranged without gaps therebetween. As a result, it is possible to prevent the crease C from extending from a gap to a mask pattern 11a.

### Supplement

The mask sheet frame body bonding apparatuses 10A, 10B, 10C according to aspect 1 of the disclosure are each a mask sheet frame body bonding apparatus configured to bond the mask sheet 11 provided with the mask pattern 11a to the frame body (frame 12), including the tension jigs (grippers 14) configured to hold both end portions (gripper end portions 11b) of the mask sheet 11 and apply a tensile force to the mask sheet 11, and the pressing member (rollers 15, 15a, 15a′, 15b, 16, 16a, 17a, 18a, 18b, 18c) other than the frame body (frame 12) configured to press at least a side of the mask sheet 11 subjected to the tensile force that is opposite to the frame body and is the front face of the mask sheet 11, between the mask pattern 11a and holding positions of the tension jigs (grippers 14).

According to the configuration described above, the mask sheet frame body bonding apparatus bonds the mask sheet provided with the mask pattern to the frame body. At this time, tension is applied to the mask sheet by the tension jigs to bond the mask sheet to the frame body in a state that does not cause a crease. However, applying tension to the mask sheet uniformly is difficult, and normally a crease is produced from the holding positions of the mask sheet by the tension jigs toward the mask pattern arranged in a center of the mask sheet.

Here, in an aspect of the disclosure, a pressing member other than the frame body configured to press at least the side of the mask sheet subjected to tensile force that is opposite to the frame body and is the front face of the mask sheet, between the mask pattern and the holding positions of the tension jigs, is provided.

Accordingly, the crease is stopped at the pressed position of the mask sheet by the roller. As a result, the portion of the mask sheet provided with the mask pattern is without the crease. Thus, the mask sheet is bonded to the frame body without the crease and with the tensile force uniformly applied, thereby making it possible to perform the vapor deposition task using the vapor deposition mask of high quality and reduce the occurrence of defective products.

Further, in an aspect of the disclosure, a method for avoiding the occurrence of the crease in the portion of the mask pattern, which is the portion that requires such avoidance, rather than eliminating all occurrences of the crease in the mask sheet, is adopted. Specifically, it is possible to achieve a reduction in the occurrence of the crease C by a pressing member, which is a simple member configured to press the area in front of the mask pattern of the mask sheet. Accordingly, adjustment of the tensile force of the tension jigs is also not required, saving time as well.

Thus, it is possible to provide the mask sheet frame body bonding apparatus that allows the mask sheet to be bonded to the frame body without producing the crease in the mask pattern by a simple method.

In the mask sheet frame body bonding apparatuses 10A, 10B, 10C according to aspect 2 of the present embodiment, preferably the pressing member (roller 15, 15a, 15a′, 15b, 16, 16a, 17a, 18a, 18b, 18c) is made from a cylindrical member.

Accordingly, the mask sheet is pressed by the pressing member made from a cylindrical member, and thus the pressed face is curved. As a result, the mask sheet is uniformly pressed without being scratched, thereby making it possible to apply uniform tension to the mask pattern.

In the mask sheet frame body bonding apparatus 10A according to aspect 3 of the disclosure, the pressing member (roller 15) presses the frame body (frame 12), sandwiching the mask sheet 11, more toward both end portion sides of the mask sheet 11 than the bonding portion of the mask sheet 11 and the frame body (frame 12).

Accordingly, the mask sheet can be pressed while sandwiched between the frame body and the pressing member. As a result, the frame body can be utilized as a pressing member. Further, the mask sheet is bonded to the frame body in a state where an adhesive strength of the frame body to the mask sheet is increased, thereby making it possible to perform bonding efficiently.

Further, in the mask sheet frame body bonding apparatus 10A, 10B, 10C according to aspect 4 of the disclosure, the pressing member (roller 15, 15a, 15a′, 15b, 16, 16a, 17a, 18a, 18b, 18c) is provided to both the front face and the rear face of the mask sheet 11, and is configured to sandwich and press the mask sheet 11.

Accordingly, the pressing member sandwiches the mask sheet, pressing the mask sheet from both the front face and the rear face thereof. As a result, the crease extended from the holding position of the tension jig toward the interior can be reliably blocked at the pressed face.

Further, in the mask sheet frame body bonding apparatus 10A according to aspect 5 of the disclosure, the pressing member (roller 15a) is positioned on the inner side of the frame body (frame 12).

As a result, the crease can be suppressed immediately in front of the mask pattern. Further, when a laser is irradiated from the upper side of the mask sheet and the mask sheet is bonded to the frame body by welding, the pressing member does not interfere.

Further, in the mask sheet frame body bonding apparatus 10A according to aspect 6 of the disclosure, the pressing member (roller 15a) is positioned on the outer side of the frame body (frame 12).

As a result, the outer side of the frame body is pressed, simplifying the pressing task. Further, when a laser is irradiated from the upper side of the mask sheet and the mask sheet is bonded to the frame body by welding, the pressing member does not interfere.

In the mask sheet frame body bonding apparatus 10A according to aspect 7 of the disclosure, the length of the pressing member (roller 15, 15a, 15a′, 15b) in the direction orthogonal to a direction in which the tensile force is applied to the mask sheet 11 is preferably longer than the bonding length when the mask sheet 11 is bonded to the frame body (frame 12).

As a result, it is possible to prevent the crease from extending outward beyond the bonding length and adversely impacting the mask pattern.

In the mask sheet frame body bonding apparatuses 10B, 10C according to aspect 8 of the disclosure, preferably a plurality of the pressing members (16a, 17a, 18a, 18b, 18c) are arranged in the direction orthogonal to the direction in which the tensile force is applied to the mask sheet 11, and a number of the pressing members (16a, 17a, 18a, 18b, 18c) having a total length corresponding to the width of the mask sheet 11 press the mask sheet 11.

For example, according to the type of display panel, the width of the mask sheets may differ. In this case, the pressing members having a single length may be shorter than the width of the mask sheet. In an aspect of the disclosure, in preparation for such a case, a plurality of pressing members are arranged in the direction orthogonal to the direction in which the tensile force is applied to the mask sheet, from the start. Then, at the time of use, the mask sheet is pressed using the number of pressing members matching the width of the mask sheet. For example, the mask sheet having a short width is pressed using one pressing member, and the mask sheet having a long width is pressed using a plurality of pressing members.

As a result, it is possible to provide the mask sheet frame body bonding apparatus capable of versatility.

In the mask sheet frame body bonding apparatuses 10B, 10C according to aspect 9 of the disclosure, the plurality of pressing members (16a, 17a) are provided on the same shaft.

Accordingly, even when the width of a single pressing member is less than the width of the mask sheet, it is possible to satisfy the width of the mask sheet 11 by arranging a plurality of the pressing members on the same shaft. As a result, in terms of the width of the mask sheet, the mask sheet can be pressed based on the same effects as when pressed using, for example, a single pressing member matching the width of the mask sheet.

In the mask sheet frame body bonding apparatus 10C according to aspect 10 of the disclosure, the plurality of pressing members (18a, 18b, 18c) are provided in a zig-zag shape on at least two shafts.

Thus, the pressing members are arranged on the two shafts, thereby blocking the crease at at least two stages, and thus increasing the effect of blocking the crease. On the other hand, the pressing members are arranged in a zig-zag shape on the two shafts, thereby allowing a decrease in the number of pressing members, and thus making it possible to block the crease efficiently using a small number of pressing members.

In the mask sheet frame body bonding apparatus 10C according to aspect 11 of the disclosure, when the plurality of pressing members (rollers 18a, 18b, 18c) provided in a zig-zag shape on the at least two shafts are viewed from both end sides of the mask sheet 11, the plurality of pressing members (rollers 18a, 18b, 18c) are preferably arranged without gaps therebetween.

As a result, it is possible to prevent the crease from extending from a gap to the mask pattern.

The manufacturing method of a vapor deposition mask according to aspect 12 of the disclosure is a manufacturing method that manufactures the vapor deposition mask 19 obtained by bonding the mask sheet 11 to the frame body using the mask sheet frame body bonding apparatus described above, the manufacturing method including the tension step for holding the mask sheet 11 at both ends and applying a tensile force to the mask sheet 11, the contacting step for fitting the mask sheet 11 inside the opening 12a of the frame body (frame 12) and bringing the frame body (frame 12) into contact with the mask sheet 11, the pressing step for pressing the front face of the mask sheet 11 by the pressing member (rollers 15, 15a, 15a′, 15b), the bonding step for bonding the mask sheet 11 to the frame body (frame 12), the pressing releasing step for releasing the pressing applied to the mask sheet 11 by the pressing member (rollers 15, 15a, 15a′, 15b) after bonding completion, the tensile force releasing step for releasing the tensile force applied to the mask sheet 11, and the cutting step for cutting the end portions of the mask sheet 11 to manufacture the vapor deposition mask 19, in that order.

Thus, according to the method described above, when the vapor deposition mask is manufactured, it is possible to provide a manufacturing method of the vapor deposition mask that allows the mask sheet to be bonded to the frame body without producing the crease in the mask pattern by a simple method.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 OLED panel
2 Substrate
3 TFT array layer
4 OLED element layer
5 Protection glass
10A, 10B, 10C Mask sheet frame body bonding apparatus
11 Mask sheet
11a Mask pattern
11b Gripper end portion (both end portions)
12 Frame (frame body)
14 Gripper (tension jig)
15, 15a, 15b Roller (pressing member)
16 Roller (pressing member)
16a Divided roller (pressing member)
16b Shaft
17a Divided roller
18a, 18b, 18c Divided roller
19 Vapor deposition mask

1. A mask sheet frame body bonding apparatus configured to bond a mask sheet provided with a mask pattern to a frame body, comprising:
a tension jig configured to hold both end portions of the mask sheet and apply a tensile force to the mask sheet; and
a plurality of pressing members other than the frame body configured to press at least a side of the mask sheet subjected to the tensile force that are opposite to the frame body and are a front face of the mask sheet, between the mask pattern and a holding position of the tension jig,
wherein the plurality of pressing members are arranged in a direction orthogonal to a direction in which the tensile force is applied,
a number of the pressing members having a total length corresponding to a width of the mask sheet are configured to press the mask sheet, and
the plurality of pressing members are provided in a zig-zag shape on at least two shafts.

2. The mask sheet frame body bonding apparatus according to claim 1,
wherein each of the plurality of pressing members is made from a cylindrical member.

3. The mask sheet frame body bonding apparatus according to claim 2,
wherein the plurality of pressing members are configured to press the frame body, sandwiching the mask sheet, more toward both end portion sides of the mask sheet than a bonding portion of the mask sheet and the frame body.

4. The mask sheet frame body bonding apparatus according to claim 1,
wherein the plurality of pressing members are provided to both the front face and a rear face of the mask sheet, and the pressing members are configured to sandwich and press the mask sheet.

5. The mask sheet frame body bonding apparatus according to claim 4,
wherein the plurality of pressing members are positioned on an inner side of the frame body.

6. The mask sheet frame body bonding apparatus according to claim 4,
wherein the plurality of pressing members are positioned on an outer side of the frame body.

7. The mask sheet frame body bonding apparatus according to claim 1,
wherein a length of each of the plurality of the pressing members in the direction orthogonal to the direction in which the tensile force is applied to the mask sheet is longer than a bonding length when the mask sheet is bonded to the frame body.

8-10. (canceled)

11. The mask sheet frame body bonding apparatus according to claim 1,
wherein, when the plurality of pressing members provided in a zig-zag shape on the at least two shafts are viewed from both end sides of the mask sheet, the plurality of pressing members are arranged without gaps therebetween.

12. (canceled)
